(19) United States
(12) Patent Application Publication
(10) Pub. No.: US 2014/0322850 A1
(43) Pub. Date: Oct. 30, 2014

(54) METHOD FOR FORMING AN ORGANIC DEVICE

(71) Applicants: Jin-Kyun Lee, Ithaca, NY (US); Alexander Zakhidov, Ithaca, NY (US); John Defranco, Ithaca, NY (US)

(72) Inventors: Jin-Kyun Lee, Ithaca, NY (US); Alexander Zakhidov, Ithaca, NY (US); John Defranco, Ithaca, NY (US)

(73) Assignee: ORTHOGONAL, INC., Ithaca, NY (US)

(21) Appl. No.: 13/638,049

(22) PCT Filed: Apr. 27, 2011
(86) PCT No.: PCT/US2011/034145

§ 371 Date: Apr. 19, 2013

Related U.S. Application Data
(60) Provisional application No. 61/343,362, filed on Apr. 27, 2010.

(51) Int. Cl. H01L 51/00; H01L 51/56

(52) U.S. Cl. CPC H01L 51/0002; H01L 51/56; H01L 51/0018
USPC 438/46; 438/82; 438/99

(57) ABSTRACT

The present invention provides a method for forming an organic device having a patterned conductive layer that includes providing a substrate, depositing organic materials over the substrate to form one or more organic layers, coating a photoresist solution over the one or more organic layers to form a photo-patternable layer, wherein the solution includes a fluorinated photoresist material and a first fluorinated solvent, selectively exposing portions of the photo-patternable layer to radiation to form a first pattern of exposed fluorinated photoresist material and a second pattern of unexposed fluorinated photoresist material, exposing the substrate to a second fluorinated solvent to develop the photo-patternable layer, removing the second pattern of unexposed fluorinated photoresist material without removing the first pattern of exposed fluorinated photoresist material, coating one or more conductive layers over the one or more organic layers and removing a portion of the one or more of the conductive layers to form a pattern. Particular embodiments of the present invention for forming arrays of top contact TFTs and a pixilated organic device are also provided.

This application is being filed on 27 Apr. 2011, as a PCT International Patent application in the name of Orthogonal, Inc., a U.S. national corporation, applicant for the designation of all countries except the U.S., and Christopher K. Ober, a citizen of the U.S., Jin-Kyun Lee, a citizen of the U.S., Alexander Zakhidov, a citizen of the U.S., Margarita Chatzichristidi, a citizen of Greece, Priscilla Taylor, a citizen of the U.S., and John DeFranco, a citizen of the U.S., applicants for the designation of the U.S. only, and claims priority to U.S. Patent Application Ser. No. 61/343,362 filed on 27 Apr. 2010.

### BACKGROUND

The present disclosure describes a method for forming an organic device. More specifically, the present disclosure describes a high resolution method for patterning a conductive material layer that is deposited over an electrically active organic layer.

Various devices are known that can employ organic semiconductor materials in conjunction with a conductive element. Included among these are Organic Light Emitting Diodes (OLEDs), Organic Thin-Film Transistors (OTFTs), Organic PhotoVoltaic (OPV) devices, and Organic Memory (OMEM). These organic electronic devices have the advantage over similar inorganic devices in that the organic materials can be much less expensive and require less expensive deposition methods than similar inorganic materials and devices. Further, in some cases, including OLEDs, it is possible to create large, active devices using organic semiconductor materials with characteristics that cannot be achieved using inorganic analogs.

Each of these example organic devices requires the deposition of multiple layers of material, including organic semiconductors and electrically conductive layers. Further, these devices often require an electrically conductive layer to be formed both on a substrate before deposition of organic materials and over the organic semiconductor layer. Further, they often require each of these electrically conductive layers to be patterned. To provide high quality devices, it is necessary to pattern this conductive layer with high resolution and to achieve a low cost device; it is desirable to pattern this conductive layer over very large substrates. The requirement for high resolution is necessary to facilitate high density OTFTs having large channel width to length ratios, high aperture ratio OLEDs, high density OMEM devices and high aperture ratio OPV devices.

In inorganic devices, it is known to apply photolithographic techniques to pattern multiple thin film layers of inorganic semiconductors and inorganic electrically conductive layers with high resolution over large substrates. Unfortunately, the photolithographic materials and solvents applied to form these devices are known to dissolve organic materials. Therefore, it is not possible to apply the photolithographic materials and solvents that are known to be used in inorganic devices to pattern multiple layers within organic devices, especially layers that include organic materials or layers that are formed on top of organic materials.

To overcome this problem, other strategies for patterning the organic materials are being developed including applying printing or selective deposition techniques, such as inkjet deposition, shadow mask deposition, vapor deposition through shadowmasks, soft and hard imprint lithography among other techniques. Unfortunately these methods have well known resolution limits, deposition speed limits, and substrate size limits that are undesirable. Further, only a subset of these techniques, specifically vapor deposition or sputtering through a shadowmask, are relevant to the deposition and patterning of highly electrically conductive metals over an organic layer. Finally, many of these methods can be applied to pattern organic semiconductors and conductors but are not equally useful for patterning inorganic conductors, which are often preferred due to low relative resistance as compared to organic conductors, over organic semiconductors.

Recently photoresist materials and solvents have been discussed in the art to facilitate the use of photolithographic techniques to pattern the organic semiconducting layers of organic devices. For example, Zakhidov et al. in an article published in Advanced Materials in 2008 on pages 3481-3484 and entitled “Hydrofluoroethers as Orthogonal Solvents for the Chemical Processing of Organic Electronic Materials” discussed a method for patterning organic material in which a fluorinated photoresist was deposited on a substrate, selectively exposed to an energy source to render insoluble a portion of the photoresist, developing the photoresist in a solvent including hydrofluoroether to develop the pattern and to remove the portion of the organic material that was not deprotected; restoring the solubility of the deprotected photoresist through the use of another solvent; depositing an active organic semiconductor over the remaining photoresist and lifting off the remaining photoresist to pattern the active organic semiconductor. As such, this paper demonstrates the patterning of a single organic semiconductor on a substrate. The method does not, however, provide a method to pattern an electrically conductive layer and especially an electrically conductive layer formed over an organic layer. The same general process has been discussed by Lee et al. in an article published in the Journal of the American Chemical Society in 2008 on pages 11564 through 11565 and entitled “Acid-Sensitive Semiperfluoroalkyl Resorcinarene: An Imaging Material for Organic Electronics”.

Hwang et al. in an article published in the Journal of Materials Chemistry in 2008 on pages 3087-3090 and entitled “Dry photolithographic patterning process for organic electronic devices using supercritical carbon dioxide as a solvent” discussed constructing a device having patterned light output by forming a photoresist layer over an organic conductor and developing a pattern in the photoresist layer using supercritical carbon dioxide. Light emitting materials and a cathode were deposited over the organic conductor and the remaining photoresist pattern to form a device in which the photoresist served as an insulator to limit the flow of electrons within some regions of the device. However, the active layers of the device were not patterned and therefore individual light emitting regions of the device could not be individually addressed to form individual light-emitting elements or pixels.

Taylor et al. in an article published in Advanced Materials on Mar. 19, 2009 on pages 2314-2317 and entitled “Orthogonal Patterning of PEDOT:PSS for Organic Electronics using Hydrofluoroether Solvents” discusses the formation of a bottom contact thin film transistor in which an organic conductor (i.e., PEDOT:PSS) is formed on a substrate, a photoresist is formed and patterned over the conductor, the conductor is etched, a second photoresist is applied and patterned before an organic semiconductor (i.e., Pentacene) is applied and patterned. While this paper discuss patterning of two organic layers, it does not discuss patterning of a conductive layer over an organic semiconductor layer as is often required in the formation of many organic electronics devices. Further, the conductor is patterned through the use of oxygen plasma etching.

As noted earlier, there is a need for a method to facilitate high resolution patterning of a conductor over an organic layer. Further, such a method should be applicable to devices formed on large substrates.

### SUMMARY

The present disclosure describes a method for high resolution patterning of a conductive layer over an organic semiconductor layer within an organic electronics device. This method includes first providing a substrate and depositing organic materials over the substrate to form one or more organic layers. A photoresist solution is coated over the one or more organic layers to form a photo-patternable layer, wherein the solution includes a fluorinated photoresist material and a first fluorinated solvent. The photo-patternable layer is then selectively exposed to radiation to form a first pattern of exposed fluorinated photoresist material and a second pattern of unexposed fluorinated photoresist material. The substrate is then exposed to a second fluorinated solvent to develop the photo-patternable layer, which removes the second pattern of unexposed fluorinated photoresist material without removing the first pattern of exposed fluorinated photoresist material. One or more conductive layers are then coated over the one or more organic layers and a portion of one or more of the conductive layers is removed to form a pattern.

At least some of the examples in the present disclosure provide the advantage of facilitating high resolution patterning of a conductive layer over an organic semiconductor layer to form low cost, high resolution, organic electronics devices. This method provides a photolithographic method for forming conductive layers over organic layers, permitting organic semiconductor devices to be formed using a method that is capable of providing extremely small feature sizes on the order of 1 micrometer or less and is applicable to large substrates. Specifically, this technique can be applied to produce high quality, high resolution top gate organic TFTs, high density organic memory devices, and OLED and OPV devices with high aperture ratios on a large substrate using processing equipment similar to equipment that is well known and accepted within the inorganic thin film semiconductor industry for creating electronic devices on very large substrates.

### BRIEF DESCRIPTION OF THE DRAWINGS

FIG. 1 flow diagram depicting the steps of one embodiment of the present invention;

FIG. 2 process diagram depicting the various stages of the development of a device formed using one embodiment of the method of the present invention;

FIG. 3A plot showing response curves for a top-contact organic TFT formed using a method according to one aspect of the present invention;

FIG. 3B plot showing response curves for a second top-contact organic TFT formed using a method according to one aspect of the present invention;

FIG. 4 flow diagram depicting the steps for forming a top-contact organic TFT according to a method according to one aspect of the present invention;

FIG. 5A-5J a series of top views of an array of organic TFTs formed according to a method according to one aspect of the present invention with each figure depicting the array at various stages of development

FIG. 6 an image of a ring oscillator formed using a method according to one aspect of the present invention; and

FIG. 7 a flow diagram depicting the steps for forming a pixilated organic device having a patterned top electrode according to an embodiment of the present invention.

### DETAILED DESCRIPTION

The present disclosure describes a method for forming an organic device on a substrate with a patterned conductive layer, where the organic device includes an active organic layer formed between the substrate and the patterned conductive layer. Specifically, the present disclosure describes a process, in which a photoresist material and the conductive layer to be deposited over an active organic layer. The photoresist material is patterned and this pattern of photoresist material is either removed, simultaneously removing a portion of the conductive layer, or is used to protect a portion of the conductive layer during an etching process, permitting the remaining portion of the conductive layer to be removed. The use of fluorinated photoresist materials and solvents permits photolithographic techniques to be utilized to pattern the conductive layer without disturbing the underlying organic materials.

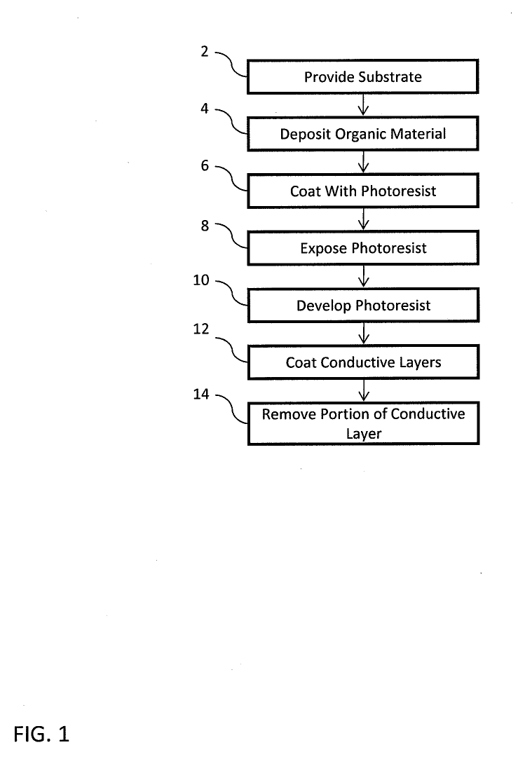

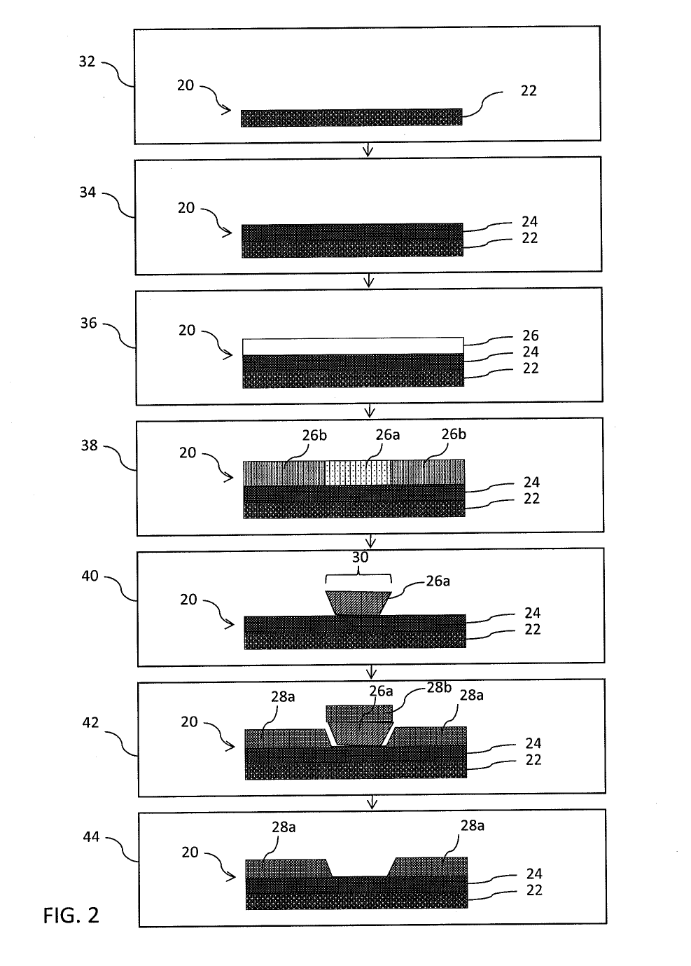

One embodiment of a method of the present invention for forming an organic device having a patterned conductive layer in contact with and over at least a portion of an organic layer is depicted in the flow diagram of FIG. 1. FIG. 2 accompanies FIG. 1 and shows an organic device 20, specifically portions of a top contact organic TFT, at various stages of development during this process. Within this method, the conductive layer is deposited over an organic layer such that it is in electrical contact with at least a portion of the organic layer and then patterned. As shown in FIG. 1, this method includes first providing 2 a substrate 22 as shown at stage 32 in FIG. 2. One or more layers of organic semiconductor material, specifically a single layer of Pentacene in the device of FIG. 2, is then deposited 4 over the substrate 22 to form one or more organic layers 24. As shown at stage 34 of FIG. 2, this forms a uniform layer of the organic layer pentacene over the substrate 22 within the active area of the device.

A photoresist solution is coated 6 over the one or more organic layers 24 to form a photo-patternable layer 26, providing the structure as shown in stage 36 of FIG. 2. Typically, after coating, this photoresist solution is dried to remove the excess solvent. This photoresist solution includes a fluorinated photoresist material and a first fluorinated solvent. Portions of the photo-patternable layer 26 are selectively exposed 8 to radiation to form a first pattern of exposed fluorinated photoresist material 26a and a second pattern of unexposed fluorinated photoresist material 26b. The first pattern of exposed fluorinated photoresist material 26a and second pattern of unexposed fluorinated photoresist material 26b is depicted in stage 38 of FIG. 2. A second drying or baking step can be performed after this exposure 8.

The substrate 22, including the photo-patternable layer 26 of photoresist material, is then exposed to a second fluorinated solvent to develop 10 the photo-patternable layer. This solvent removes the second pattern of unexposed fluorinated photoresist material 26b without removing the first pattern of exposed fluorinated photoresist material 26a. As a result, the first pattern of exposed fluorinated photoresist material 26a remains on the substrate 22 as shown in stage 40 of FIG. 2. As shown in FIG. 2, in certain embodiments, it is useful for the remaining first pattern of exposed fluorinated photoresist material 26a to be undercut, such that the width 30 of the remaining first pattern of exposed fluorinated photoresist near the top of the first pattern of exposed fluorinated photoresist is greater than the width of the first pattern of exposed fluorinated photoresist at a point closer to the substrate 22. While this undercut is desirable within some embodiments, other shapes of this first pattern of exposed fluorinated photoresist can be desirable in other embodiments.

One or more conductive layers 28 are then coated 12 over the one or more organic layers 24. As shown in stage 42 of FIG. 2, this conductive layer 28 is coated over the organic layer 24 in the areas where the second pattern of unexposed fluorinated photoresist was removed and over the first pattern of exposed fluorinated photoresist 26a in the areas where this first pattern of exposed fluorinated photoresist 26a remains over the organic layer 24. As shown in FIG. 2, the one or more conducting layers 28 can be coated through the use of a line of sight method, such as vapor deposition. Using a process such as this, the undercut provided in the first pattern of exposed fluorinated photoresist material, permits shadowing of the organic layer, such that the conductive layer 28 contains voids due to shadowing of the organic layer by the first pattern of exposed fluorinated photoresist material 26a. As such, the conductive layer 28 can be divided into discontinuous segments, specifically first segment 28a and second segment 28b of conductive layer 28 in FIG. 2. This void permits the third solvent access to the first pattern of exposed fluorinated photoresist material 26a. In another embodiment, the first pattern of exposed fluorinated photoresist material will not be undercut or a nondirectional coating process, such as sputtering can be applied which would permit the conductive layer 28 to be coated against the remaining first pattern of exposed fluorinated photoresist material 26a. However, the thickness of this first pattern of exposed fluorinated photoresist material 26a can be such to create pinholes or other voids in this layer along the edges of the first pattern of exposed fluorinated photoresist material. Such voids are important when the conductive layer is a metal or a doped inorganic oxide such that the third solvent can gain access to the first pattern of exposed fluorinated photoresist material. These voids are not necessarily as important when the conductive layer is an organic material.

Finally, a portion 28b of the first pattern of exposed fluorinated photoresist material is applied to remove 14 a portion of one or more of the conductive layers 28 to form a patterned conductive layer 28a. The portion 28b of one or more of the conductive layers can be removed through one of multiple processes. Shown in FIG. 1, the one or more conductive layers 28a, 28b are coated over the first pattern of exposed fluorinated photoresist material 26a and the step of developing 12 the photoresist permits the first pattern of exposed fluorinated photoresist material 26a to be removed, removing 12 a segment 28b of one or more of the conductive layers through liftoff. Therefore, the step of applying the first pattern of exposed fluorinated photoresist material to remove 14 a segment 28b of one or more of the conductive layers involves exposing the substrate 22 to a third fluorinated solvent to strip 16 the exposed fluorinated photoresist material 26a and the segment 28b of the one or more conductive layers 28a, 28b that were deposited over the first pattern of exposed fluorinated photoresist material 26a.

Within the present disclosure, the term “substrate” refers to any support on which organic materials can be coated to provide structural integrity. Substrates known in the art include rigid substrates, such as those typically formed from glass, and flexible substrates, such as typically formed from stainless steel foil or plastic. The substrate 22 can also provide a portion of an environmental barrier to protect the organic material from moisture or oxygen, but this is not required. The substrate 22 can be opaque, transparent or semitransparent. The substrate 22 can further include one or more inorganic layers, such as metal buss lines or inorganic semiconductor materials for conducting electricity to the organic device. The substrate 22 can include nonconductive layers of organic material to perform functions, such as insulating the active organic layer from conductive elements on the substrate or smoothing the surface of the substrate to permit a uniform layer of active organic materials 24 to be formed.

The term “organic layer” in the present disclosure refers to a layer of organic chemical compounds that provide an active electrical function. The organic materials from which the organic layer 24 will be formed will commonly be semiconductors and will typically be formed in one or more thin layers, often less than 50 nm in thickness. These organic materials can be small molecule organic materials, monomers, polymers or mixtures of these materials. Within processes described in examples in the present disclosure, small molecule and monomer materials will commonly be coated using vacuum deposition. However they can also be solution coated. Polymers will typically be solution coated. Within some preferred embodiments of the present invention, these organic materials will be blanket coated. That is they will be deposited to uniformly coat a single large area of the substrate 22 to form the organic layer 24. However, this is not required and in some embodiments, these materials can be patterned on the substrate 22 as they are deposited forming an organic layer 24 that is discontinuous across the surface of the substrate 22. In a preferred embodiment, it is desirable for the last active organic material to be deposited before coating 6 the photoresist or coating 12 the conductive layer to contain polymer strands to provide stability to the organic layer. As such, the step of depositing organic materials over the substrate includes depositing at least one polymeric organic material and the photoresist solution is coated directly on top of the at least one polymeric organic material. By providing an active electrical function, the organic material serves to conduct electricity, serves as a semiconductor to control the flow of electricity, or serves as an insulator to prevent or reduce the flow of electricity.

In examples described in the present disclosure a photoresist solution is coated “over” the one or more organic layers to form a photo-patternable layer. The term “over” is defined such that an organic layer is deposited on the substrate prior to coating the photo-patternable layer. In some embodiments, the photo-patternable layer will be coated immediately on top of one or more organic layers. In another embodiment, one or more organic layers will be deposited and a patterned inorganic layer will be created over the organic layer, covering a portion of the organic layer and the photoresist solution will be coated such that it is in direct contact with a portion of the organic layer, without having any intermediate inorganic layer. In further embodiments, an inorganic layer is formed over the organic layer before applying the photoresist solution. Although it is possible that the inorganic layer could provide protection to the organic layer, in practical devices voids within the inorganic layer will often prevent such an inorganic layer from providing effective protection to the organic layer from the photoresist solution and the second and third solvents. Therefore, in some embodiments it is important to use the fluorinated photoresist and solvents described in the present disclosure to achieve high yield even in circumstances where the organic layer is deposited onto the substrate prior to exposing the substrate to a photoresist solution even when the organic layer is somewhat protected by an intervening inorganic layer.

The term “conductive layer” refers to layer or a combination of multiple thin film layers formed after an organic layer, wherein the layer or combination of thin film layers functionally provide a single conductive element which is capable of creating an electrical field within the organic layer. The conductive layer can be transparent, semi-transparent, or opaque. Typical conductive layers useful in embodiments of the present invention will have a thickness of between 10 nm to permit the formation of a continuous film and less than 300 nm to permit the film to be permeated by the solvents described in the present disclosure. This conductive layer can be formed from organic or inorganic materials capable of providing electricity to the organic semiconductor layers. However, in some preferred embodiments of the present invention, these conductive layers will include an inorganic metal. This inorganic metal will preferably be applied through vapor deposition or sputtering.

Typical inorganic materials useful in forming such a conductive layer will include metals such as silver, gold, platinum, copper and aluminum; as well as certain doped metal oxides, such as indium tin oxide or indium zinc oxide. Once again, conductive layers can be formed using multiple methods including printing or sputtering. However, as discussed earlier, it can be desirable in certain embodiments to deposit the inorganic conductive layers using evaporation or other methods that provide line of sight deposition.

Typical organic materials for forming the conductive layer include highly ordered polymers, such as PEDOT/PSS. Conductive layers formed from organic materials can be formed using numerous methods, including printing methods. However, to increase deposition speed and decrease process time, it is preferred that these materials be deposited using blanket-coating methods including hopper or slot coating.

The fluorinated photoresist material can be a resorcinarene, a random copolymer of perfluorooctyl methacrylate with 2-nitrobenzyl methacrylate (to form “FOMA-NBMA”), a random copolymer of perfluorooctyl methacrylate with tert-butyl methacrylate (to form “FOMA-TBMA”), a random copolymer of perfluorodecyl methacrylate with 2-nitrobenzyl methacrylate (to form “FDMA-NBMA”), a random copolymer of perfluorodecyl methacrylate with tert-butyl methacrylate (to form “FDMA-TBMA”), block copolymers of FOMA-NBMA, FOMA-TBMA, FDMA-NBMA, FDMA-TBMA, derivatives thereof or other polymer photoresist or molecular glass photoresist having sufficient content to permit the photoresist to be dissolved in a fluorinated solvent such as a solvent formed from a hydrofluorether. This fluorinated photoresist can be solubilized in a hydrofluoroether such as methyl nonafluorobutyl ether and then coated onto a substrate described in the present disclosure. The solvent can then be evaporated to form a photo-patternable layer. This first solvent will typically also include a photo-acid generator, for example N-hydroxynaphthalamide perfluorobutylsulfonate or other known photo-acid generator. In the presence of proper exposure, this photo-acid generator will liberate H+, which will react with the fluorinated photoresist material to transform it into an insoluble form. These materials and their use in conjunction with fluorinated solvents for performing photolithographic steps have been discussed in more detail in a co-pending document with the serial number PCT/US09/44863 and entitled “Orthogonal Processing of Organic Semiconductors,” the contents of which is incorporated in its entirety herein.

In a preferred (but non-limiting) embodiment this photoresist can be a material composed of a copolymer of 1H,1H,2H,2H-perfluorodecyl methacrylate (FDMA) and tert-butyl methacrylate (TBMA). This material was found to have a high fluorine content to make it soluble in the fluorinated solvents described in the present disclosure. This statistical copolymer of FDMA and TBMA was prepared by free radical polymerization under a nitrogen atmosphere. A 25 ml round bottom flask equipped with a stir bar was filled with 1.4 g of FDMA, 0.6 g of TBMA, 0.01 g of AIBN and 2 ml of trifluorotoluene as a solvent. After polymerization, the reaction mixture was poured into hexane to precipitate the polymer and then filtered and dried under vacuum. The molecular weight of the copolymer was determined to be 30400 by size-exclusion chromatography and the molar composition of FDMA:TBMA was found to be 35 mol %:65 mol % using ¹H NMR (Varian Inova-400 spectrometer) analysis with CDCl₃—CFCl₃ (v/v—1:3.5) as a solvent. The FDMA component of the resist is responsible for the solubility of the copolymer in fluorinated solvents whereas the TBMA groups in the unexposed regions make the copolymer less polar in the butyl-protected state. Upon exposure to a photogenerated acid, these protecting groups undergo a chemically amplified deprotection reaction. The resulting polar methacrylic acid (MAA) units decrease copolymer solubility in fluorinated solvents. After the photo-patternable layer 26 is formed from this material together with a photoacid generator and exposed 8, the exposed pattern can be treated with a solubilizing agent, for example a silazine such as HMDS. This treatment re-protects the P(FDMA-co-MAA) film with siloxane groups and makes it soluble within fluorinated solvents to facilitate its removal for liftoff.

In another preferred (but non-limiting) embodiment the photoresist can be a copolymer of FOMA and TBMA. For example, a solution of 110.10 g (0.7743 mol.) of tert-butyl methacrylate, (TBMA), 330.07 g (0.7636 mol.) of 1H,1H,2H,2H-perfluorooctyl methacrylate, (“FOMA”), 874.2 g of Novec 7600 and 5.51 g (0.0335 mol.) of azobisisobutyronitrile, (“AIBN”) was stirred in a jacketed reaction flask. The flask jacket was connected to a programmable, constant temperature bath (“CTB”) capable of heating and maintaining a set jacket temperature. The solution was sparged with nitrogen at a rate of 0.5 L/minute for 1 hour at ambient temperature. A CTB program was initiated which heated the reaction jacket to 68° C., holds this temperature for 1 hour, heats to 72° C. and holds for 1 hour, and finally heats to 76° C. and holds for 12 hours. When the heating program was completed, the CTB was set to cool the reaction mixture to ambient temperature. The clear, colorless polymer solution obtained was diluted to a viscosity target by the addition of 3.714 kg of Novec™ 7600, and a small sample was removed and dried under vacuum for later characterization. In one embodiment, under yellow lights, 22.0 g of CIBA/BASF CGI-1907 photo acid generator (“PAG”) (5% by weight of the original dry weight of TBMA) was dissolved in the remaining photoresist solution. The solution was filtered, and was then ready for use in the same fashion as was described above for FDMA-TBMA.

It should be noted that the resorcinarene, FOMA:TBMA and FDMA:TBMA random and block copolymers are chemically amplified resists. Within embodiments of the present invention, this attribute of these resists can be particularly desirable since they enable the expose photoresist step 8 to be performed through the application of a relatively low energy UV light exposure. This low energy UV light exposure will preferably require less than 1000 mJ/cm² and more preferably less than 100 mJ/cm² of energy. This is helpful since many organic materials useful in forming the one or more organic layers 24 will decompose in the presence of UV light and therefore, reduction of the energy during this step permits the photoresist to be exposed 8 without causing significant damage to the underlying one or more organic layers 24. Further, due to the high fluorine content in each of these photoresists, they are both hydrophobic and oleophobic. That is, the resulting material repels or resists both water and most organic solvents, permitting these materials to serve as an in-process encapsulation layer to protect the underlying organic materials from moisture and damage from organic solvents.

Fluorinated solvents appropriate for use of the first, second or third fluorinated solvent is perfluorinated or highly fluorinated liquids, which are typically immiscible with organic solvents and water. Among these solvents are one or more hydrofluoroethers (HFEs) such as methyl nonafluorobutyl ether, methyl nonafluoroisobutyl ether, isomeric mixtures of methyl nonafluorobutyl ether and methyl nonafluoroisobutyl ether, ethyl nonafluorobutyl ether, ethyl nonafluoroisobutyl ether (HFE 7100), isomeric mixtures of ethyl nonafluorobutyl ether and ethyl nonafluoroisobutyl ether (HFE 7200), 3-ethoxy-1,1,1,2,3,4,4,5,5,6,6,6-dodecafluoro-2-trifluoromethyl-hexane (HFE 7500), 1,1,1,2,2,3,4,5,5,5-decafluoro-3-methoxy-4-trifluoromethyl-pentane, 1,1,1,2,3,3-hexafluoro-4-(1,1,2,3,3,3,-hexafluoropropoxy)-pentane (HFE 7600) and combinations thereof. The fluorinated solvent may also be selected from a broad range of fluorinated solvents, such as chlorofluorocarbons (CFSs): CₓCl_{y}F_{z}, hydrochlorofluorocarbons (HCFCs): CₓCl_{y}F_{z}H_{w}, hydro fluorocarbons (HFCs): CₓF_{y}H_{z}, purfluorocarbons (FCs); CₓF_{y}, hydrofluoroethers (HFEs): CₓH_{y}OC_{z}F_{w}, perfluoroethers: CₓF_{y}OC_{z}F_{w}, purfluoroamines: (CₓF_{y})₃N, trifluoromethyl (CF3)-substituted aromatic solvents: (CF3)xPh [benzotrifluoride, bis(trifluoromethyl)benzene]. Other fluorinated solvents are also known and could be equally well applied for use in the first, second, or third fluorinated solvent.

The photoresist solution will typically include the photoresist material as described above in a fluorinated solvent, for example HFE 7500. Additionally, when the photoresist is a chemically amplified resist material, such as a resorcinarene or the FDMA/TBMA copolymer, this solution will additionally contain a photoacid generator. An appropriate photoacid generator is 2-[1-methoxy]propyl acetate (PGMEA).

Generally, it is desirable that the first fluorinated solvent have a higher boiling point than the second and third fluorinated solvent. Generally, the first fluorinated solvent will typically have a boiling point above 110 degrees Celsius while the second and third fluorinated solvents will have a boiling point below 110 degrees Celsius. For example, the first solvent can include HFE 7500 having a boiling point of 131 degrees Celsius at atmospheric pressure while the second and third solvents can include HFE 7200 having a boiling point of 76 degrees Celsius at atmospheric pressure. The selection of these boiling points in this way serves to prevent any of the first fluorinated solvent remaining after the first baking step from being evaporated during later baking steps, reducing the dimensional stability of the first pattern of exposed photoresist material. Further, any baking or drying step performed after the expose photoresist step 8 should be performed at a temperature less than the boiling point of the first fluorinated solvent and typically under 100 degrees Celsius.

The third fluorinated solvent will typically include a solubilizing agent to permit the pattern of exposed photo-patternable material to become soluble in the fluorinated solvent. For example, materials such as a silazine, for example hexamethyldisilazane (HMDS; 1,1,1,3,3,3-hexamethyldisilazane) can be added to the third fluorinated solvent to render the first pattern of exposed photo-patternable material soluble. Such an agent can be added to a fluorinated solvent to form the third solvent, for example the third solvent can contain 5% HMDS and 95% HFE 7200. Other useful solubilizing agents include isopropyl alcohol (IPA) which can be formulated similarly to form a third solvent containing 5% IPA and 95% HFE 7200.

As noted earlier, a portion of the photoresist can be exposed to radiation to form a first pattern of exposed fluorinated photoresist material 26a and a second pattern of unexposed photoresist material 26b. For example, an ultraviolet lamp having a wavelength of 248 nm can be used to radiate the photoresist or a lamp with another wavelength, for example 365 nm can be applied. Experiments have verified that when the photoresist is formed from resorcinarene, an exposure of an exposure of about 84 mJ cm² at 248 nm is adequate to enable the necessary reaction while a dose of about 2700 mJ cm² is required when the wavelength is 365 nm.

As noted earlier, in some embodiments, it is useful for the exposure to create a profile that is an “undercut” profile, which is defined as having a width 30, as shown in FIG. 2, measured along a line parallel to the substrate 22 that is larger at a distance farther from the substrate 22 than a distance nearer the substrate 22, thus having a shape similar to the shape of 26a. This undercut profile can be created through a number of possible methods; however, when applying the chemically amplified resists as described earlier, the inventors have observed that such a profile can be achieved by defocusing the radiation source, thus creating a defocused exposure.

The process provided in FIG. 1 has been applied to form a top contact thin film transistor, a portion of the layers from which were shown in FIG. 2. Experiments have demonstrated that the second pattern of unexposed fluorinated photoresist material was removed from the top of the organic layer 24, permitting a low contact resistance between the conductive layer 28a and the organic layer 24. Therefore, this process was demonstrated to form a high quality top contact thin film transistor. This top contact organic TFT was shown to have certain advantages over the bottom contact organic TFTs discussed by Taylor in the prior art. Specifically the organic layer described in the present disclosure is uniform across the entire substrate and the contact resistance between the conductive layer and the organic layer is low permitting the transistor to have a low threshold.

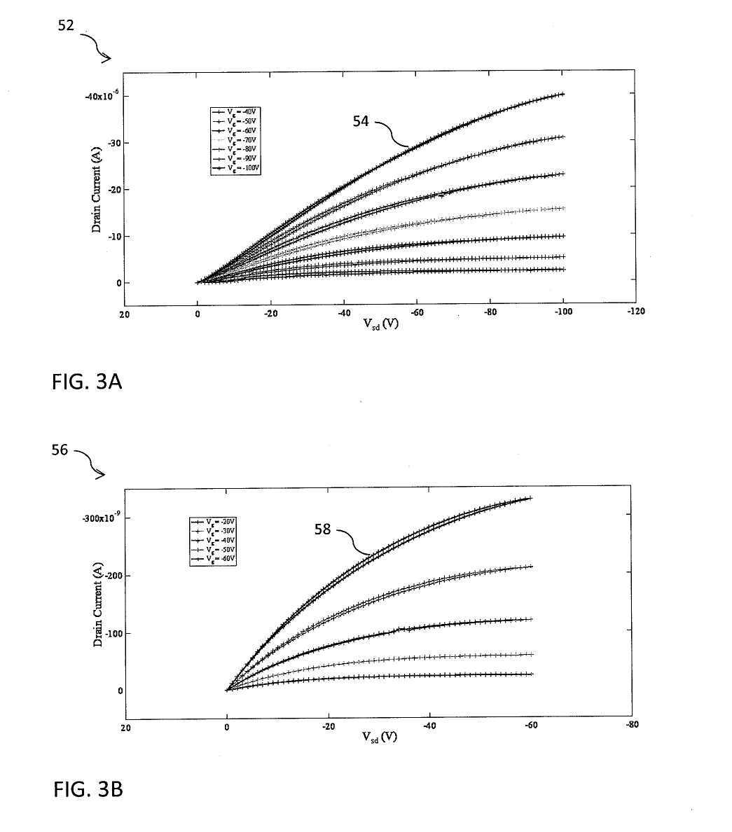

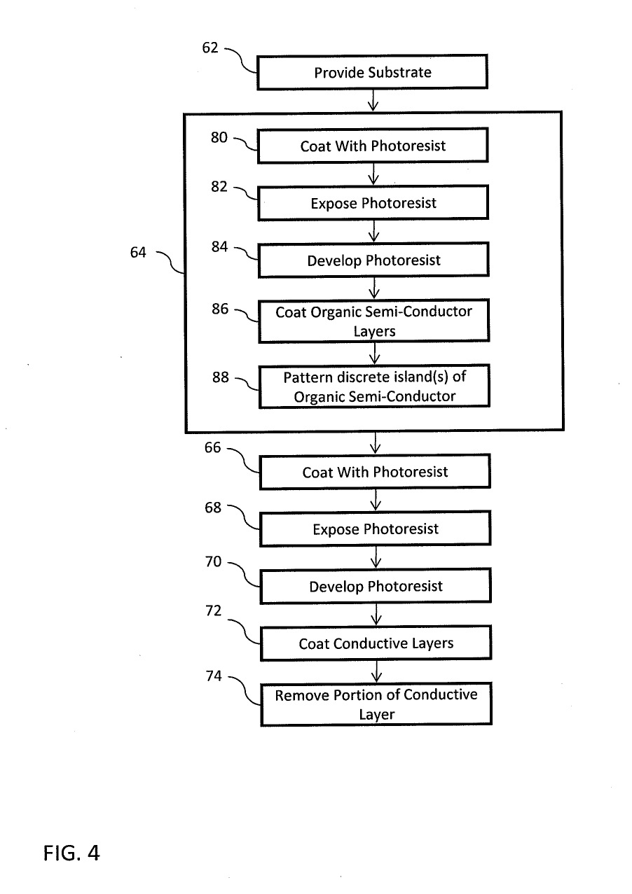

The current at the drain of a TFT, which was formed using a method described in the present disclosure, as a function of the voltage differential between the source and drain is shown in the plot 52 of FIG. 3a. As this figure shows, the TFT permits the modulation of current at the drain as a function of gate voltage as illustrated by the curves 54. By fitting an equation I=W/2L*u*Cᵣ*(V_{G}−V_{TH})² to these curves where I is the drain current, W and L are the width and length of the TFT channel, respectively, u is the mobility of the semiconductor in the TFT, Cᵣ is the capacitance per unit area of the gate dielectric, V_{G} is the gate voltage and V_{TH} is the threshold voltage of the TFT; it was determined that the mobility of the resulting TFT could be as high as 0.45 cm²V⁻¹s⁻¹. This is significantly higher than the mobility of the TFT reported by Taylor of 0.03 cm²V⁻¹s⁻¹ for a bottom contact TFT formed from similar materials.

Alternatively, top contact TFTs were formed using Poly (3-Hexylthiophene)—(P3HT) as an organic semiconductor. The performance of the top contact TFT formed using this semiconductor is shown in the plot 56 of FIG. 3B. Once again drain current can be controlled by selection of the gate voltage as shown by curves 58. The mobility for this device was 0.01 cm²V⁻¹s⁻¹, which is lower than the mobility of the device employing Pentacene as expected. However, the mobility of this device is superior to devices using the same organic semiconductor that have been reported in the prior art.

Critical to the formation of such a top-contact TFT is the ability to successfully pattern the conductive layer 28 on top of an organic layer 24 such that the interface is robust between the two layers 24, 28, having a low resistivity. The inventors have demonstrated for the first time, the formation and removal of a photolithographic step on top of an organic layer to form such a top contact TFT. This process of performing photolithographic steps on top of organic layers, however, enables the construction of multiple, valuable organic electronic structures.

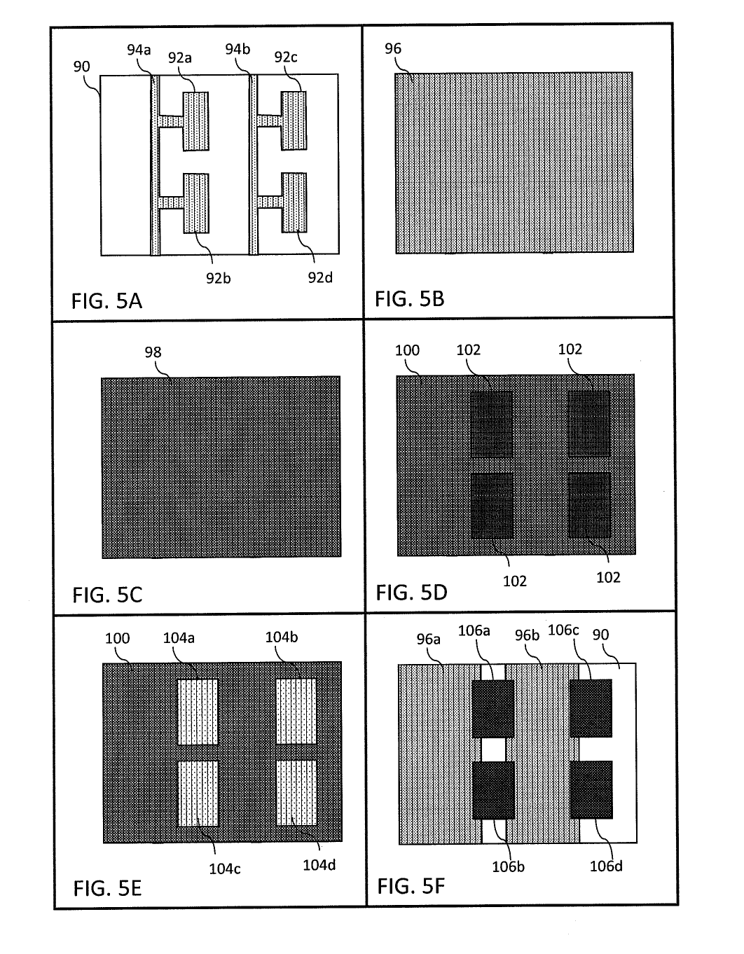

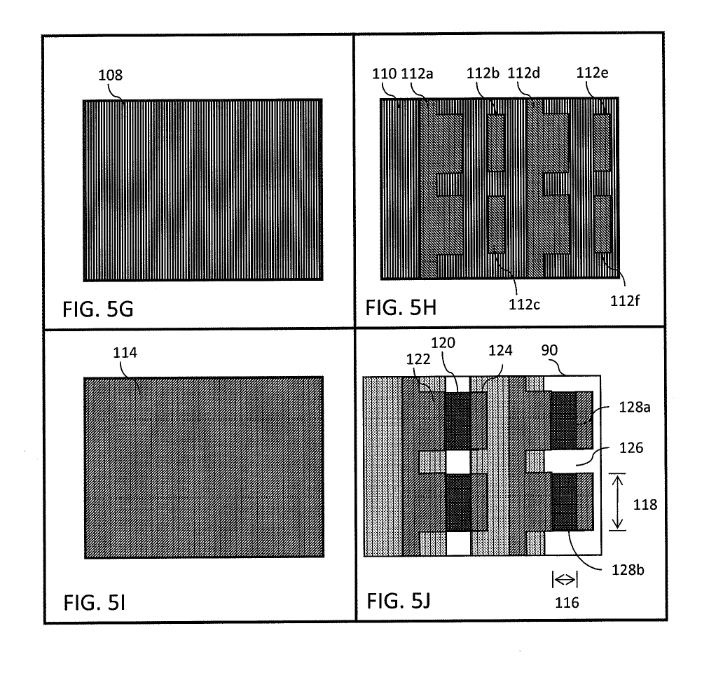

Although the method described in the present disclosure can be important to facilitate the formation of a single top-contact thin-film transistor, the method of described in the present disclosure can be utilized to form an array of multiple top-contact TFTs on a single substrate that is coated with a one or more conductive layers wherein these conductive layers are originally formed from a single conductive layer that is continuous over a large portion of the substrate. One method for forming such an array of multiple top-contact TFTs using a method described in the present disclosure is provided in the flow chart of FIG. 4 and a top view of one device formed through this process is depicted at various stages of development within FIG. 5A through FIG. 5J. As shown in FIG. 4, a substrate is provided 62. This substrate 90, as shown in FIG. 5A has an array of one or more gate conductors 92a, 92b, 92c, 92d and gate busses 94a, 94b formed on the substrate 90. The gate conductors will provide the gates for four separate top-contact TFTs within this example and the two gate busses 94a, 94b provide lines to provide a signal to the gate conductors 92a, 92b, 92c, 92d. This substrate 90 can additionally have an insulating or dielectric layer 96 formed over the gate busses and importantly the one or more gate conductors 92a, 92b, 92c, 92d. The gate conductors, gate busses and insulating layer 96 can be formed from inorganic materials and can be patterned using known methods of the prior art, including through the use of traditional photolithographic techniques. Alternately, portions of these structures can be patterned using fluorinated photoresist materials and solvents and could be formed from organic materials.

An organic semiconductor layer can then be formed 64 over the substrate such that it consists of an array of one or more discrete islands of organic semiconductor 106a, 106b, 106c, 106d (as shown in FIG. 5F), wherein each discrete island of organic semiconductor is continuous over the substrate within the area of each TFT. Each island of organic semiconductor will form the channel of a TFT and will provide contact to the drain and source of the TFT. Note that the organic semiconductor materials in this case are not continuous between the areas of neighboring TFTs. The organic semiconductor materials could be coated such that discrete islands of the organic semiconductor materials are formed within the area of each of the one or more TFTs using any desired method. However, according to a preferred embodiment of the present invention, these discrete islands are formed using the steps indicated in detail within step 64 of FIG. 4.

Within the preferred embodiment, the method for forming 64 the discrete islands includes coating 80 a photoresist solution over the substrate 90 to form a photo-patternable layer 98 as shown in FIG. 5C. This photo-patternable layer is selectively exposed 82 to radiation to form a third pattern of exposed photoresist material 100 and a fourth pattern of unexposed photoresist material 102, wherein the third pattern of exposed photoresist material 100 is arranged to provide separation between the discrete islands of organic semiconductor material. The photo-patternable layer is then exposed to a solvent to develop 84 the photo-patternable layer, removing the fourth pattern of unexposed photoresist material without removing the third pattern of exposed photoresist material. As shown in FIG. 5E, the result is a substrate with the third pattern of exposed photoresist material covering the majority of the substrate, with voids 104a, 104b, 104c, 104d to the structure of the substrate that was formed before formation of the photo-patternable layer. Next an organic semiconductor layer is coated 86 over the third pattern of exposed photoresist material 100 and the voids 104a, 104b, 104c, 104d. Finally, the third pattern of exposed photoresist material is exposed to an additional solvent to remove the third pattern of exposed photoresist material and the portions of the organic semiconductor layer over the third pattern of exposed photoresist material to pattern 88 the organic semiconductor layer into discrete islands of organic semiconductor materials 106a, 106b, 106c, 106d as shown in FIG. 5F within the area of each top-contact TFT within the array of top-contact TFTs. Once one or more discrete islands of organic-semiconductor materials have been formed on the substrate 90, the remaining steps (e.g., steps 66 through 74) of the method to form the array of one or more top-contact TFTs can be performed.

The flow chart in FIG. 4 shows the remaining steps of this process. These include coating 66 a photoresist solution over the organic semiconductor layer to form a photo-patternable layer 108 as shown in FIG. 5G. This solution is then dried. Portions of the photo-patternable layer are then selectively exposed 68 to radiation to form a first pattern of exposed photoresist material 110 and a second pattern of unexposed photoresist material, indicated by pattern areas 112a 112b 112c 112d 112e, wherein a portion of the first pattern of exposed photoresist material is deposited 70 over one or more of the discrete islands of organic semiconductor material 106a, 106b, 106c, 106d in FIG. 5F and a portion of the first pattern of exposed photoresist material is deposited between the one or more discrete islands of organic semiconductor material. The portion of this first pattern of exposed photoresist material deposited over the one or more discrete islands of organic semiconductor material will define the channel of the TFT and the portion of this first pattern of exposed photoresist material deposited between one or more discrete islands of organic-semiconductor material will provide a separation between neighboring top-contact TFTs within the array of top-contact TFTs. The photo-patternable layer is then exposed to a second solvent to develop 70 the photo-patternable layer, removing the second pattern of unexposed photoresist material without removing the first pattern of exposed photoresist material. One or more conductive layers are then coated 72 over at least a portion of the organic semiconductor materials and the first pattern of exposed photoresist material to form an electrical contact between the one or more conductive layers and the organic semiconductor materials on at least two sides of the first pattern of exposed photoresist materials. This conductive layer is shown as 114 in FIG. 51. Finally, the first pattern of exposed photoresist material is exposed to a third solvent to remove 74 the first pattern of exposed photoresist material and at least a portion of the one or more conductive layers 114 to form a channel 120 between two discrete portions 122 and 124 of the one or more conductive layers for each of the thin-film transistors in the array of thin-film transistors as shown in FIG. 5J. The channel has a length 116 and a width 118, the width 118 is typically more than twice the length 116. Note that in preferred embodiments, the first pattern of exposed photoresist material is a two-dimensional structure which simultaneously defines at least the channel 120 of one top-contact TFT and a separation region 126 between two adjacent top-contact thin film transistors 128a, 128b in the array of top-contact thin film transistors formed on the substrate 90. In this preferred embodiment, the step of exposing the first pattern of exposed photoresist material to a third solvent removes the first pattern of exposed photoresist material and a portion of the one or more conductive layers to define not only the channel itself but additionally the ends of the channel in the dimension parallel to the length of the channel to form the separation region 126 between adjacent top-contact TFTs 128a, 128b.

It can be noted that as described thus far, the method described in the present disclosure uses a photolithographic process to perform liftoff of the one or more conductive layers on top of the organic layer to remove 14 a portion of the conductive layer. It is also possible to coat the one or more conductive layers over the organic layers before coating the substrate with the photoresist solution to form the photo-patternable layer. This photo-patternable layer can then be selectively exposed using techniques such as electron beam lithography to form very small features and the second pattern of unexposed fluorinated photoresist material removed. Finally, a portion of one or more of the conductive layers can be removed using an etching process in the areas where the photo-patternable layers were removed. Thus the first pattern of exposed photoresist material is once again applied to remove 14 a portion of the conductive layer.

It should be noted that after the substrate 90 is coated with the photoresist solution, it is generally necessary to dry or bake the substrate to remove excess solvent from the photoresist solution. In actuality, the substrate is typically baked twice. The first baking step is typically conducted after the photoresist solution is deposited over the substrate to remove the excess solvent. Secondly, the substrate is often baked after selectively exposing portions of the photo-patternable layer to eliminate unwanted byproducts, such as nitrobenzyl groups that are created during the expose step and that can reduce the structural stability of the exposed resist material, or to thermally activate the cleaved photoacids when applying chemically amplified resists.

In one aspect of the present disclosure, the active semi-conductive and conductive organic materials, as well as certain conductive metals are highly reactive with oxygen and can be degraded by moisture. As such, the processing and development of devices containing these materials is sometimes critical. Small molecule organic materials and thin films of metal or doped metal oxides are often deposited within a vacuum which is void of moisture and oxygen. Therefore, contamination by oxygen or moisture is not an issue in these environments. However, at some of the photoresist materials and solvents described in the present disclosure cannot be handled in a vacuum. Therefore, it may by necessary to transport the substrate out of the vacuum after completion of vacuum deposition steps and into inert environments having near atmospheric pressure. In one embodiment, the photoresist materials and solvents will be applied within a dry nitrogen environment. Further, once the photoresist materials are applied, they provide a moisture barrier until they are removed. Therefore, the substrate can be removed from the dry nitrogen environment after an initial drying period and transferred to a baking oven within a normal atmospheric environment which contains moisture.

The term “near atmospheric pressure” refers to an environment that is not a vacuum. When vapor depositing small molecule OLEDs to obtain high efficiency and lifetime in embodiments of the present invention, it is helpful to remove the substrate from the vacuum to coat 66, 80 the photoresist, expose 68, 82 the photoresist, develop 70, 84 the photoresist, and liftoff a portion of the photo-patternable layer to pattern 88 the semiconductor layer or remove 74 a portion of the conductive layer. Therefore, these operations must be performed in at “near atmospheric pressure”. This term therefore applies to environments with between 0.01 Torr and 1000 Torr of pressure, more preferably between 1 and 1000 Torr of pressure and more preferably between 100 and 1000 Torr of pressure. Alternatively, “vacuum” refers to an environment with an atmospheric pressure significantly less than 0.01 Torr and commonly less than 10⁻⁴ Torr.

When applying polymeric active semi-conductive and conductive organic materials, as well as certain conductive metals or doped metal oxides, these materials can be coated using solution processing. For instance, it is possible to coat polymers in solution and it is possible to coat metal pastes or metal nanoparticles in solution. When applying these types of materials, the step of coating the one or more organic layers will include depositing solutions containing these materials over the substrate and a drying process to remove the solvents from these materials. This coating and drying process can also take place in a dry nitrogen environment at, near or below atmospheric pressure.

In embodiments of the present invention, it is possible to coat the organic semiconductor materials, the conductive materials or the photolithographic materials using a printing process or other selective deposition technique. However, such methods are not necessary and are often slower than blanket-coating processes. Therefore, in preferred embodiments of the present invention at least one and preferably all three of these processes include a blanket coating process in which the coating process involves coating these materials in one continuous sheet across the surface of the substrate. When evaporating or sputtering materials, this will include performing these steps in such a way that the entire surface to be coated is exposed to the deposition process such that at least the entire width or length of the area to be coated is simultaneously exposed. When performing solution coating, this step will include exposing at least the entire width or length of the area to be coated simultaneously, for instance using slot or hopper coating techniques but can include two dimensional coating techniques, such as spin coating.

To further illustrate the usefulness of the present invention, an example method according to the present invention was applied to form a hybrid electronic circuit containing both inorganic and organic materials. Specifically, this method was applied to form a ring oscillator containing a connected network of TFTs using organic semiconductor materials. To build this ring oscillator poly(2,5-bis(thiophene-2-yl)-3,7-ditri-decanyltetrathienoacene) (P2TDC13FT4) was selected as the organic semiconductor. This polymer was selected since it can easily be formed via spin-coating and is environmentally stable, permitting this spin coating to be performed in air.

To develop this device, a substrate, specifically a silicon wafer, was provided 2. A 40 nm gold film was deposited and patterned to be the Gate electrode for each of 5 TFTs within the ring oscillator. Then 50 nm of Al₂O₃ followed by 2 nm of SiO₂ were deposited by atomic layer deposition and patterned to form the gate dielectric for each TFT. SiO₂ termination was selected since silicon oxide can be easily primed by silanes, such as hexamethyldisilazane. Then a Cr/Au interconnect layer was formed and patterned to connect the TFTs to one another. Each of these layers was formed from inorganic layers and could have been formed with traditional photolithographic methods, photoresists, and solvents. However, in this device, each of these layers was patterned using the photolithographic methods and materials as discussed within this disclosure. Specifically, liftoff was performed using highly-fluorinated photoresists and hydrofluoroethers as solvents.

Next 50 nm of P2TDC13FT4 was deposited to form the organic layer 24 within the area of the channel for each of the five TFTs. Note at this point, the P2TDC13FT4 is continuous over the channel of each TFT. Thus this patterning step creates discrete islands of organic semiconductor material (e.g., 106a) within the channel area of each TFT. Finally, the process in certain embodiments of the present invention was applied with 40 nm of Au being applied over the first pattern of exposed fluorinated photoresist material to serve as the conductive layer 28. This photoresist material was lifted off using hydrofluoroether as a solvent to remove a portion of the conductive layer according to an embodiment of the present invention.

A semi-perfluoroalkyl reorcinarene small molecule compound was used as the resist for the first two layers, namely the gate and the dielectric layers. A polymeric resist, specifically the copolymer of FDMA and TBMA, was used as the photoresist for the remaining three steps, specifically the interconnect layer, the organic layer and the top conductive Au layer.

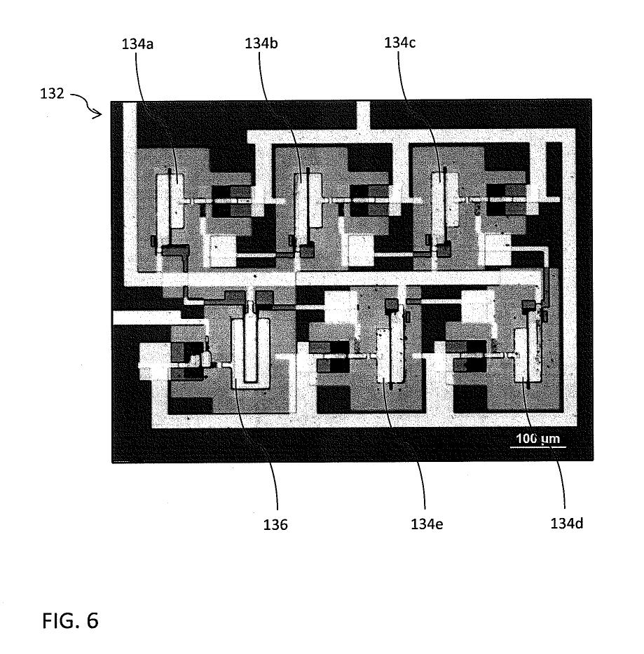

A microscopic image of a ring oscillator 132 formed using the process according to certain embodiments of the present invention is shown in FIG. 6. As shown, the TFTs 134a, 134b, 134c, 134d, and 134e have a channel length 116 of 1 micrometer. Also shown is an inverter 136 formed using the method in an embodiment of the present invention. Alignment of the layers was always better than 1 micrometer, demonstrating the alignment accuracy of the present method. For these devices mobilities of 0.05 to 0.1 cm²V⁻¹s⁻¹ with a threshold voltage of −7V were observed. These devices had an on/off ratio reaching 10⁵. The ring oscillator began to oscillate at about 12 Volts and reach an oscillation frequency of 15 kHz at 55V. This corresponds to a delay of 7 microseconds per stage, which compares favorably with organic TFT ring oscillators made with other methods. Note that the TFTs were successfully formed, indicating the ability to pattern an inorganic conducting layer 28 over an organic layer 24 to form the channel of the TFTs. These devices were formed with high yield and a small channel length, demonstrating the ability of the method according to certain aspects of the present invention to successfully pattern small features in an organic or inorganic conducting layer that is deposited on top of an organic layer of active semiconductor. Further, since the materials according to certain embodiments of the present invention provide the ability to use fabrication equipment similar to that used for traditional photolithographic patterning of purely inorganic devices, this demonstrates the usefulness of certain embodiments of the present invention to create organic electronics devices using equipment and methods similar to those used within the inorganic electronics industry. In addition, this device demonstrated the ability to use the fluorinated photoresists and solvents to pattern inorganic and organic layers that are deposited on the substrate such that the layers are interspersed with one another. As such, a single set of chemistry can be applied to form hybrid devices that include both organic and inorganic compounds, facilitating the development of devices in which the class of material is selected based upon its utility without being constrained by the available patterning technology.

As indicated earlier, the method according to certain embodiments of the present invention provides the capability to pattern a conductor that is coated over and in electrical contact with an organic semiconductor material using photolithographic techniques. This method can be useful in the fabrication of various organic device in which it is necessary to pattern a conductive material layer that is formed on top of and in electrical contact with at least a portion of a layer of organic semiconductor. Besides top contact TFTs as described earlier, this method can be applied to other organic electronics devices. Among these applications is the patterning of the top electrode in organic LED or OLED devices, patterning of the top electrode in organic memory devices, and patterning of the top electrode in organic photovoltaic devices. Each of these devices can require the patterning of a conductive layer that is coated over an organic semiconductor. Further, organic memory devices can require the patterning of two conductive layers within the device, one of which is a charge trapping layer, the other of which serves as an electrode. In such devices, it should be acknowledged that each conductive layer can be patterned using separate but identical process steps.

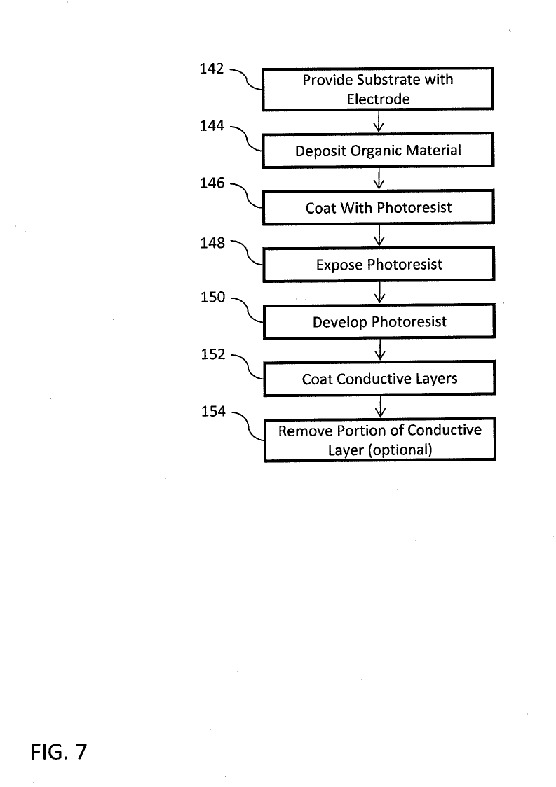

Therefore, the method can be used to form a pixilated organic device. The term pixilated refers to a device having an array in at least one dimension but preferably in two dimensions where the array includes multiple, individually addressable elements. This can be achieved using a process, such as the one shown in FIG. 7. As shown this process includes first providing 142 a substrate having a first conductive layer over the substrate to form a first electrode. In some embodiments, it can be necessary to pattern this first electrode, for instance into stripes or a two-dimensional array of independent electrode elements.

Organic semiconductor materials are then deposited 144 over the first conductive layer to form a first stack of one or more organic semiconductor layers. Typically, these layers will be formed in continuous layers as their lateral resistivity is high enough to preclude cross-talk between individual elements in the pixilated device. These layers will typically include multiple layers of organic semiconductor materials, including layers for transport of holes or electrons, injection of holes or electrons, and an active layer for emitting light in an OLED device or absorbing light and converting the energy to electricity in an OPV device.

A photoresist solution is then coated 146 over the one or more organic layers to form a photo-patternable layer. According to aspects of the present disclosure, the photoresist solution includes a fluorinated photoresist material and a first fluorinated solvent as described earlier. This photo-patternable layer is then dried and selectively exposed 148 to radiation to form a first pattern of exposed fluorinated photoresist material and a second pattern of unexposed fluorinated photoresist material. In these embodiments, the first pattern of exposed fluorinated photoresist material is formed within the area between adjacent pixels while the second pattern of exposed fluorinated photoresist material defines the location of the second electrode for the organic device of interest.

The substrate, and the photo-patternable layer is exposed to a second fluorinated solvent to develop 150 the photo-patternable layer, removing the second pattern of unexposed fluorinated photoresist material without removing the first pattern of exposed fluorinated photoresist material. As such, the area where the second electrode is to be deposited is free from photoresist material and the photoresist material only remains in the area between segments of the second electrode.

Next, a second conductive layer is coated 152 over the one or more organic layers and the first pattern of exposed fluorinated photoresist material. The portions of the conductive layer that is in direct contact with the one or more organic layers form the second electrode for the device. In some embodiments of the present invention, the first pattern of exposed fluorinated photoresist material can be designed to prevent the conductive layer from being continuous over this structure. For example, by providing walls of photoresist material that have a height greater than the thickness of the conductive layer or providing a first pattern of exposed fluorinated photoresist material having a strong undercut, the conductive layer can be formed such that it is not continuous between sections of the first pattern of exposed photoresist material. Under these conditions, because the photoresist is electrically insulating, the device can be complete at this stage. However, at least in some instances, the conductive layer can be continuous over the first pattern of exposed photoresist material. When the photoresist material is structured such that the conductive layer is continuous over the first pattern of exposed fluorinated photoresist material, this photoresist material must be removed to remove the portion of the conductive layer deposited over the first pattern of exposed fluorinated photoresist material. Therefore, the optional step of exposing 154 the substrate to a third solvent containing a fluorinated solvent can be performed to remove the exposed fluorinated photoresist material and a portion of the one or more conductive layers to pattern the second electrode for the organic device, forming a second patterned electrode, thus forming a pixilated device.

The invention has been described in detail with particular reference to certain preferred embodiments thereof, but it will be understood that variations and modifications can be effected within the spirit and scope of the invention.

### LIST OF REFERENCE LABELS IN THE DRAWINGS

2 providing substrate step
4 deposit organic semiconductor material step
6 coat photoresist solution step
8 expose fluorinated photoresist step
10 develop photo-patternable layer step
12 coat conductive layer step
14 remove portion of conductive layer step
20 organic device
22 substrate
24 one or more organic layers
26 photo-patternable layer
26a first pattern of exposed fluorinated photoresist material
26b second pattern of exposed fluorinated photoresist material
28 conductive layer
28a first segment of conductive layer
28b second segment of conductive layer
30 width near the top of the first pattern of exposed fluorinated photoresist material
32 substrate stage
34 organic-coated substrate stage
36 photoresist-coated substrate stage
38 patterned photoresist stage
40 developed photoresist stage
42 conductive layer—coated stage
44 completed top contact TFT stage
52 plot
54 curves
56 plot
58 curves
62 provide substrate step
64 pattern organic semiconductor into discrete islands step
66 coat photoresist step
68 expose photoresist step
70 develop photoresist step
72 coat conductive layers step
74 remove portion of conductive layer step
80 coat with photoresist step
82 expose photoresist step
84 develop photoresist step
86 coat organic semiconductor step
88 pattern organic semiconductor step
90 substrate
92a gate conductor
92b gate conductor
92c gate conductor
92d gate conductor
94a gate buss
94b gate buss
96 insulating layer
98 photo-patternable layer
100 third pattern of exposed photoresist material
102 fourth pattern of unexposed photoresist material
104a void
104b void
104c void
104d void
106a discrete island of semiconductor material
106b discrete island of semiconductor material
106c discrete island of semiconductor material
106d discrete island of semiconductor material
108 photo-patternable layer
110 first pattern of exposed photoresist material
112a second pattern of unexposed photoresist material
112b second pattern of unexposed photoresist material
112c second pattern of unexposed photoresist material
112d second pattern of unexposed photoresist material
112e second pattern of unexposed photoresist material
114 conductive layer
116 channel length
118 channel width
120 channel
122 portion of conductive layer
124 portion of conductive layer
126 separation region
128a top contact thin film transistor
128b top contact thin film transistor
132 ring oscillator
134a organic TFT
134b organic TFT
134c organic TFT
134d organic TFT
134e organic TFT
136 inverter
142 provide substrate with electrode step
144 deposit organic material step
146 coat with photoresist step
148 expose photoresist step
150 develop photoresist step
152 coat conductive layers step
154 remove portion of conductive layer step

What is claimed is:

1) A method for forming an organic device having a patterned conductive layer, including:
a. providing a substrate;
b. depositing organic materials over the substrate to form one or more organic layers;
c. coating a photoresist solution over the one or more organic layers to form a photo-patternable layer, wherein the solution includes a fluorinated photoresist material and a first fluorinated solvent;
d. selectively exposing portions of the photo-patternable layer to radiation to form a first pattern of exposed fluorinated photoresist material and a second pattern of unexposed fluorinated photoresist material;
e. exposing the substrate to a second fluorinated solvent to develop the photo-patternable layer, removing the second pattern of unexposed fluorinated photoresist material without removing the first pattern of exposed fluorinated photoresist material;
f. coating one or more conductive layers over the one or more organic layers; and
g. removing a portion of the one or more of the conductive layers to form a pattern.

2) The method according to claim 1, wherein the one or more conductive layers are coated over the first pattern of exposed fluorinated photoresist material and the step of removing a portion of one or more of the conductive layers includes exposing the substrate to a third fluorinated solvent to remove the exposed fluorinated photoresist material and the portion of the one or more conductive layers deposited over the first pattern of exposed fluorinated photoresist material.

3) The method according to claim 1, wherein the one or more conductive layers are coated over the organic layers before coating the substrate with the photoresist solution, the photo-patternable layer is then formed, selectively exposed and the second pattern of unexposed fluorinated photoresist material is removed and further wherein the step of removing a portion of one or more of the conductive layers includes an etching process.

4) The method of claim 1, wherein the one or more organic layers are deposited to form a continuous layer.

5) The method of claim 1, further including two baking steps, wherein a first baking step is performed after coating a photoresist solution over the one or more organic layers and a second baking step is performed after selectively exposing portions of the photo-patternable layer.

6) The method of claim 1 wherein the photoresist solution contains a co-polymer of perfluorooctyl methacrylate and tert-butyl methacrylate.

7) The method of claim 1, wherein the step of coating of the one or more organic layers is performed in a vacuum and wherein the step of coating at least one photoresist layer is performed at atmospheric pressure in a dry environment.

8) The method of claim 1, wherein the step of coating the one or more organic layers includes a solution deposition and a drying process.

9) The method of claim 1, wherein the solution deposition coating is a blanket deposition process.

10) The method of claim 1, wherein the conductive layer is formed from one or more of a metal, a conductive metal oxide, or a conductive polymer.

11) The method of claim 1, wherein the photo-patternable layer includes a chemically amplified resist.

12) The method of claim 1, wherein the first fluorinated solvent has a boiling point above 110 degrees C.

13) The method of claim 10, wherein the second fluorinated solvent has a boiling point lower than the boiling point of the first fluorinated solvent.

14) The method of claim 1, wherein the method is used to form an organic TFT, an organic LED, an organic memory element, an organic photovoltaic device or a touch screen.

15) The method of claim 1, wherein the step of depositing organic materials over the substrate includes depositing at least one polymeric organic material and wherein the photoresist solution is coated directly on top of the at least one polymeric organic material.

16) A method of forming an array of one or more top-contact thin film transistors, including:
a. providing a substrate;
b. forming an organic semiconductor layer over the substrate, including one or more discrete islands of organic semiconductor material which is continuous over the substrate within a portion of each TFT;
c. coating a photoresist solution over the organic semiconductor layer to form a photo-patternable layer;
d. selectively exposing portions of the photo-patternable layer to radiation to form a first pattern of exposed photoresist material and a second pattern of unexposed photoresist material, wherein at least a portion of the first pattern of exposed photoresist material is located over one or more of the discrete islands of organic semiconductor material and a portion of the first pattern of exposed photoresist material is located between one or more of the discrete islands of organic semiconductor material;
e. exposing the substrate to a second solvent to develop the photo-patternable layer, removing the second pattern of unexposed photoresist material without removing the first pattern of exposed photoresist material;
f. coating one or more conductive layers over at least a portion of the organic semiconductor materials and the first pattern of exposed photoresist material to form electrical contact between the one or more conductive layers and the organic semiconductor materials on at least two sides of the first pattern of exposed photoresist materials within at least one discrete island of organic semiconductor material; and
g. exposing the first pattern of exposed photoresist material to a third solvent to remove the first pattern of exposed photoresist material and a portion of the one or more conductive layers to form a channel in the one or more conductive layers for each of the thin-film transistors in the array of thin-film transistors, the channel having a length and a width, the width more than twice the length.

17) The method according to claim 16, wherein the first pattern of exposed photoresist material is a two-dimensional structure defining the channel and a separation region between two or more top-contact thin film transistors in the array of top-contact thin film transistors; and the step of exposing the first pattern of exposed photoresist material to a third solvent removes the first pattern of exposed photoresist material and a portion of the one or more conductive layers to additionally form the ends of the channel in the dimension parallel to the length of the channel.

18) A method of forming a pixilated organic device, including:
a. providing a substrate having a first conductive layer over the substrate to form a first electrode;
b. depositing organic semiconductor materials over the first conductive layer to form a first stack of one or more organic semiconductor layers;
c. coating a photoresist solution over the one or more organic layers to form a photo-patternable layer, wherein the photoresist solution includes a fluorinated photoresist material and a first fluorinated solvent;
d. selectively exposing portions of the photo-patternable layer to radiation to form a first pattern of exposed fluorinated photoresist material and a second pattern of unexposed fluorinated photoresist material;
e. exposing the substrate to a second fluorinated solvent to develop the photo-patternable layer, removing the second pattern of unexposed fluorinated photoresist material without removing the first pattern of exposed fluorinated photoresist material; and
f. coating a second conductive layer over the one or more organic layers and the first pattern of exposed fluorinated photoresist material to form a second electrode.

19) The method according to claim 18, further including exposing the substrate to a third solvent containing a fluorinated solvent to remove the exposed fluorinated photoresist material and a portion of the one or more conductive layers to pattern the second electrode for the organic device, forming a second patterned electrode.

20) The method according to claim 18, wherein the organic device is an OLED, an OPV device, or an OMEM device and wherein the method of patterning the second electrode provides an array of individually-addressable elements.
